(19) United States
(12) Patent Application Publication
(10) Pub. No.: US 2014/0043216 A1
(43) Pub. Date: Feb. 13, 2014

(54) BORON NITRIDE ANTISTICTION FILMS AND METHODS FOR FORMING SAME

(71) Applicant: Chiung-Wen Tang, Taiwan R.O.C. (TW)

(72) Inventor: Chiung-Wen Tang, Taiwan R.O.C. (TW)

(73) Assignee: QUALCOMM MEMS Technologies, Inc., San Diego, CA (US)

(21) Appl. No.: 13/572,485

(22) Filed: Aug. 10, 2012

(51) Int. Cl. G02B 26/00; B05D 5/12; C23C 16/44; G09G 3/00

(52) U.S. Cl. 345/32; 359/290; 427/58

(57) ABSTRACT

This disclosure provides systems, methods and apparatuses for providing a boron nitride layer in a cavity of an optical electromechanical systems (EMS) device. The boron nitride layer can be deposited, for example using ALD, after removal of the sacrificial layer to define an EMS cavity. The boron nitride layer may reduce stiction between a first and second electrode structure of the EMS device.

### TECHNICAL FIELD

This disclosure relates to coatings for electromechanical systems and devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

During operation of the electromechanical systems device the movable electrode repeatedly contacts the stationary electrode. The repeated contact causes wear to the surfaces. The contacting surfaces can sometimes “stick” or become hard to separate from an actuated position to an open conditions due to physical and electrostatic attraction known in the art as stiction.

### SUMMARY

The systems, methods and devices of this disclosure each have several innovative aspects, no single one of which is solely responsible for the desirable attributes disclosed herein.

One innovative aspect of the subject matter described in this disclosure can be implemented in an optical electromechanical systems device. The device includes a first electrode structure having a first surface, a second electrode structure having a first surface and a second surface opposite the first surface. The second electrode structure is movable for operation of the optical electromechanical systems device. The device further includes a collapsible cavity between the first surface of the first electrode structure and the first surface of the second electrode structure. The device also includes a boron nitride layer exposed to the cavity and over at least one of the first surface of the first electrode structure and the first surface of the second electrode structure.

In some implementations, the boron nitride can line the cavity on both the first surface of the first electrode structure and the first surface of the second electrode structure. In such implementations, the boron nitride layer can at least partially cover the second surface of the second electrode structure. In some implementations, the boron nitride layer can line the cavity on only the first surface of the first electrode structure. In some implementations, the boron nitride layer can have a hardness of about 3400 kg/mm²-4500 kg/mm². In some implementations, the boron nitride layer can line the cavity on the first surface of the first electrode structure, which is defined by an insulator over a conductive absorber layer. In some implementations, a thickness of the insulator, the conductive absorber layer, and the boron nitride layer can be less than about 45 nm. In some implementations, the boron nitride layer can be conformal over at least one of the first surface of the first electrode structure and the first surface of the second electrode structure. In some implementations, a majority of the first electrode structure can be parallel to the second electrode structure in each of open and closed states. In some implementations, the second electrode structure can be connected to the second electrode structure around a perimeter of the second electrode structure by support structures. In some implementations, a middle portion of the second electrode structure can deflect towards the first electrode structure when in a closed state. In some implementations, the electromechanical systems device can be an interferometric modulator.

Another innovative aspect of the subject matter described in this disclosure can be implemented in a method for manufacturing an optical electromechanical systems device. The method includes forming a first electrode. The method further includes forming a sacrificial layer over the first electrode. A second electrode is formed over the sacrificial layer. The sacrificial layer is removed, thereby releasing the optical electromechanical systems device and forming a cavity between the first electrode and the second electrode such that at least on of the first and second electrodes is movable. The method also includes forming a boron nitride layer on at least one of the first and second electrodes. The boron nitride layer is positioned such that it is exposed to the cavity after the sacrificial layer is removed.

In some implementations, forming the boron nitride layer can include depositing a boron nitride layer over the first electrode before forming the sacrificial layer over the first electrode. In some implementations, forming the boron nitride layer can include depositing a boron nitride layer over the first electrode before forming the sacrificial layer over the first electrode.

Another innovative aspect of the subject matter described in this disclosure can be implemented in an optical electromechanical systems device. The device includes a first electrode, a second electrode that is movable for operation of the optical electromechanical device, and a cavity defined between the first electrode and the second electrode. The device further includes a means for reducing stiction covering a surface of at least one of the first electrode and the second electrode exposed to the cavity. The means for reducing stiction includes boron nitride.

In some implementations, the means for reducing stiction can include a boron nitride layer on surfaces facing the cavity of each of the first electrode and the second electrode. In some implementations, the second electrode can be substantially parallel to the first electrode in each of an open state and a closed state.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIGS. 2A-2E are cross-sectional illustrations of varying implementations of IMOD display elements.

FIG. 3 is a flow diagram illustrating a manufacturing process for an IMOD display or display element.

FIGS. 4A-4E are cross-sectional illustrations of various stages in a process of making an IMOD display or display element.

FIGS. 5A-5B show examples of cross-sectional schematic illustrations of electromechanical systems devices.

FIGS. 6A-6B show examples of cross-sectional schematic illustrations of stages in a method of making an interferometric modulator.

FIG. 6C shows an example of an enlarged cross-sectional schematic illustration of a movable electrode structure for an interferometric modulator.

FIG. 6D shows an example of an enlarged cross-sectional schematic illustration of a stationary electrode structure for an interferometric modulator.

FIGS. 7A-7F show examples of cross-sectional schematic illustrations of stages in a method of making an interferometric modulator.

FIG. 7G shows an example of an enlarged cross-sectional schematic illustration of a stationary electrode structure for an interferometric modulator.

FIG. 8 shows an example of a flow diagram illustrating a method for processing electromechanical systems devices.

FIGS. 9A and 9B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Processing electromechanical systems devices can include a release etch process to etch a portion of each device to form an internal cavity in the device. A boron nitride antistiction layer can be formed such that it borders on the cavity to reduce stiction in the device. The boron nitride layer can include a layer formed before release of the device, for example using chemical vapor deposition (CVD) or physical vapor deposition (PVD), or after release of the device, for example using atomic layer deposition (ALD).

Particular implementations of the subject matter described in this disclosure can be implemented to realize one or more of the following potential advantages. The hardness of the antistiction layer and wear-resistance can preserve the antistiction properties of the antistiction layer even after long use of the device. In an interferometric modulator implementation, the boron nitride layer can allow the thickness of the optical stack to be decreased, which may allow the cavity size to increase. The use of an antistiction layer formed from boron nitride (BN) can result in improved electromechanical systems device performance, such as increased lifespan of the device in comparison to use of materials such as aluminum oxide. The use of BN antistiction layers can increase device resistance to humidity and other contaminants, which can result in improved electrical properties and device performance and stability. An optical electromechanical systems device, such as an interferometric modulator, can experience issues related to stiction as large surface areas of the device may be in contact during operation of the device.

An example of a suitable EMS or MEMS device or apparatus, to which the described implementations may apply, is an optical EMS device, such as a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

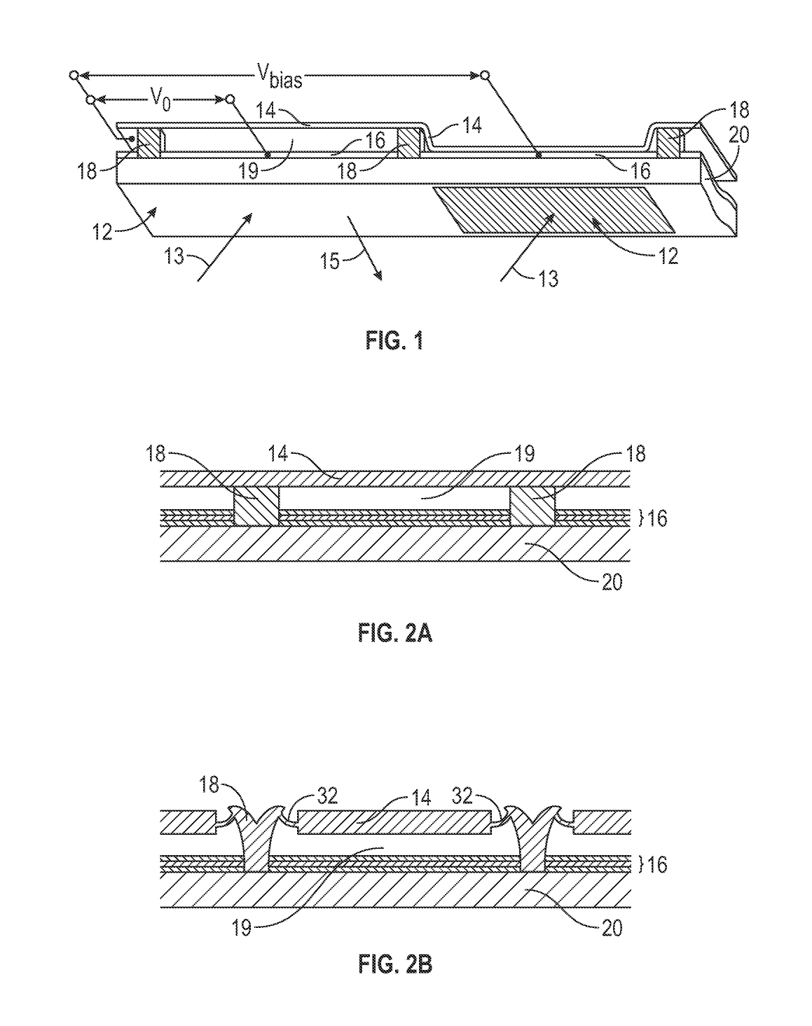

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of primary colors and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer. The optical stack 16, including both conductive and insulating layers, can serve as a stationary electrode structure for an EMS device.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than approximately 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

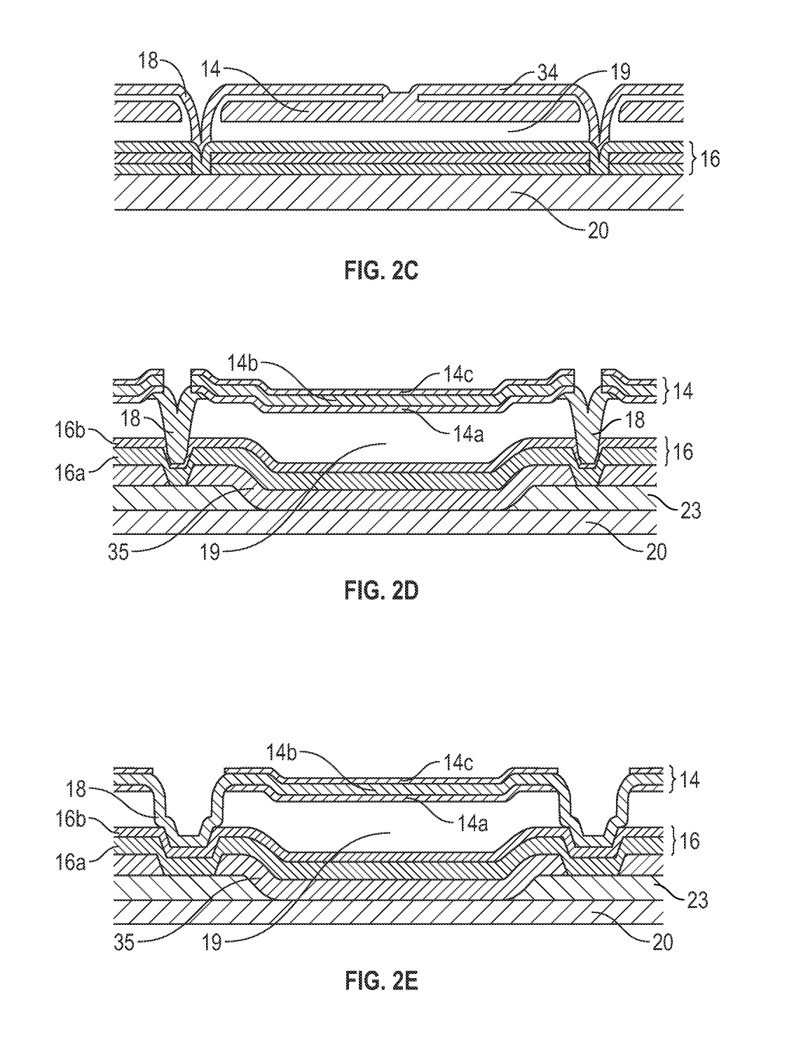

The details of the structure of IMOD displays and display elements may vary widely. FIGS. 2A-2E are cross-sectional illustrations of varying implementations of IMOD display elements. FIG. 2A is a cross-sectional illustration of an IMOD display element, where a strip of metal material is deposited on supports 18 extending generally orthogonally from the substrate 20 forming the movable reflective layer 14. In FIG. 2B, the movable reflective layer 14 of each IMOD display element is generally square or rectangular in shape and attached to supports 18 at or near the corners, on tethers 32. In FIG. 2C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as implementations of “integrated” supports or support posts 18. The implementation shown in FIG. 2C has additional benefits deriving from the decoupling of the optical functions of the movable reflective layer 14 from its mechanical functions, the latter of which are carried out by the deformable layer 34. This decoupling allows the structural design and materials used for the movable reflective layer 14 and those used for the deformable layer 34 to be optimized independently of one another.

FIG. 2D is another cross-sectional illustration of an IMOD display element, where the movable reflective layer 14 includes a reflective sub-layer 14a. The movable reflective layer 14 rests on a support structure, such as support posts 18. The support posts 18 provide separation of the movable reflective layer 14 from the lower stationary electrode, which can be part of the optical stack 16 in the illustrated IMOD display element. For example, a gap 19 is formed between the movable reflective layer 14 and the optical stack 16, when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 2D, some implementations also can include a black mask structure 23, or dark film layers. The black mask structure 23 can be formed in optically inactive regions (such as between display elements or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, at least some portions of the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. In some implementations, the black mask structure 23 can be an etalon or interferometric stack structure. For example, in some implementations, the interferometric stack black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (or carbon tetrafluoride, CF₄) and/or oxygen (O₂) for the MoCr and SiO₂ layers and chlorine (Cl₂) and/or boron trichloride (BCl₃) for the aluminum alloy layer. In such interferometric stack black mask structures 23, the conductive absorbers can be used to transmit or bus signals between conductors of the lower, stationary electrodes (the optical stacks 16) of each row or column. In some implementations, a spacer layer 35 can serve to generally electrically isolate electrode layers (or conductors) in the optical stack 16 (such as the absorber layer 16a) from the conductive layers in the black mask structure 23.

FIG. 2E is another cross-sectional illustration of an IMOD display element, where the movable reflective layer 14 is self-supporting. While FIG. 2D illustrates support posts 18 that are structurally and/or materially distinct from the movable reflective layer 14, the implementation of FIG. 2E includes support posts that are integrated with the movable reflective layer 14. In such an implementation, the movable reflective layer 14 contacts the underlying optical stack 16 at multiple locations, and the curvature of the movable reflective layer 14 provides sufficient support that the movable reflective layer 14 returns to the unactuated position of FIG. 2E when the voltage across the IMOD display element is insufficient to cause actuation. In this way, the portion of the movable reflective layer 14 that curves or bends down to contact the substrate or optical stack 16 may be considered an “integrated” support post. One implementation of the optical stack 16, which may contain a plurality of several different layers, is shown here for clarity including an optical absorber 16a, and a dielectric 16b. In some implementations, the optical absorber 16a may serve both as the electrode layer for the stationary electrode and as a partially reflective layer. In some implementations, the optical absorber 16a can be an order of magnitude thinner than the movable reflective layer 14. In some implementations, the optical absorber 16a is thinner than the reflective sub-layer 14a.

In implementations such as those shown in FIGS. 2A-2E, the IMOD display elements form a part of a direct-view device, in which images can be viewed from the front side of the transparent substrate 20, which in this example is the side opposite to that upon which the IMOD display elements are formed. In these implementations, the back portions of the device (that is, any portion of the display device behind the movable reflective layer 14, including, for example, the deformable layer 34 illustrated in FIG. 2C) can be configured and operated upon without impacting or negatively affecting the image quality of the display device, because the reflective layer 14 optically shields those portions of the device. For example, in some implementations a bus structure (not illustrated) can be included behind the movable reflective layer 14 that provides the ability to separate the optical properties of the modulator from the electromechanical properties of the modulator, such as voltage addressing and the movements that result from such addressing.

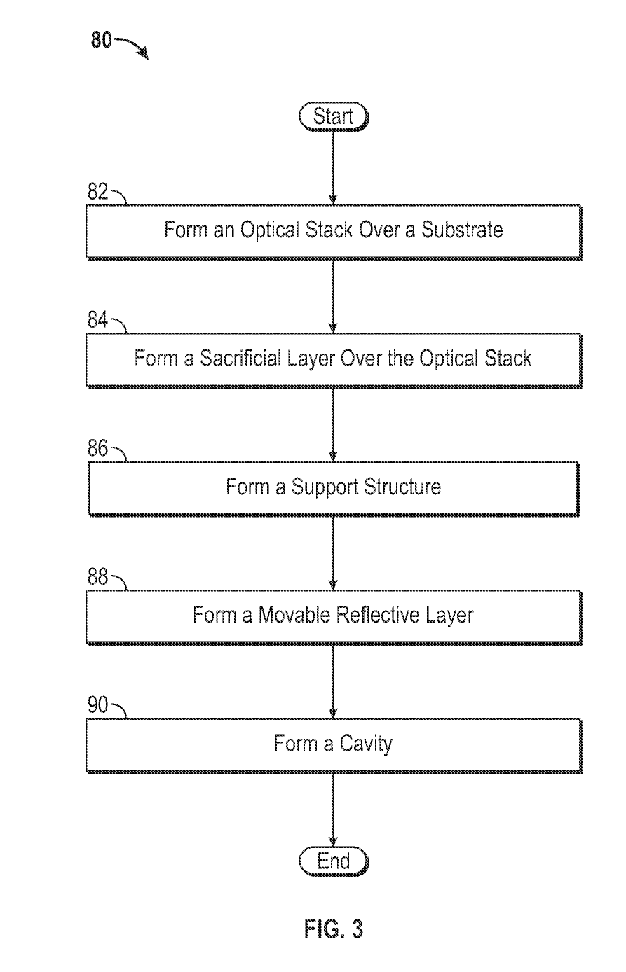

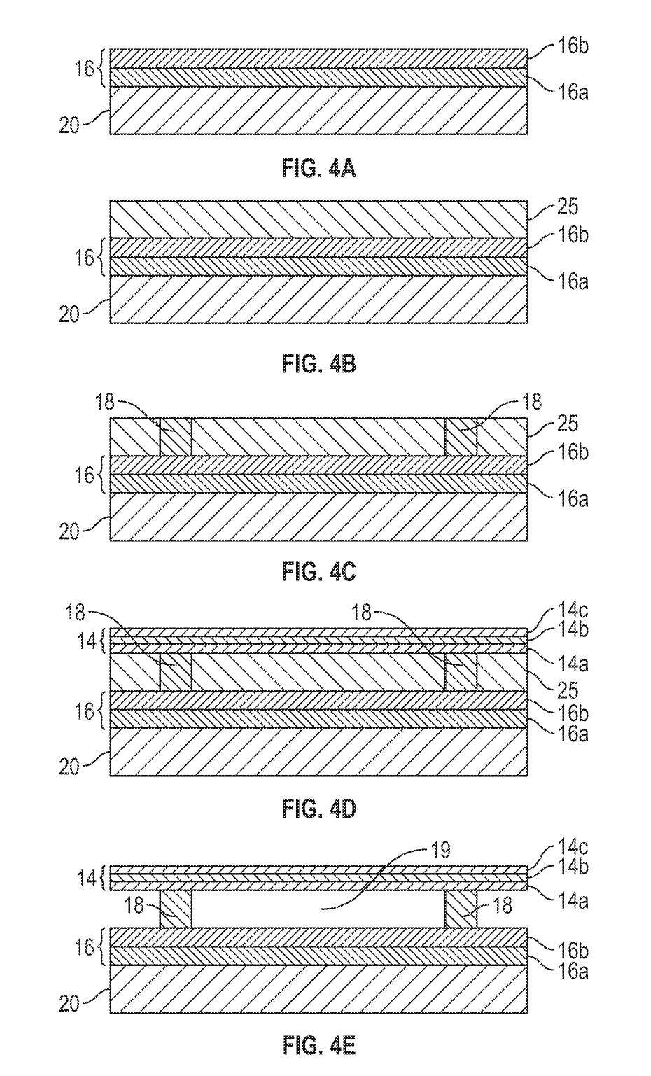

FIG. 3 is a flow diagram illustrating a manufacturing process 80 for an IMOD display or display element. FIGS. 4A-4E are cross-sectional illustrations of various stages in the manufacturing process 80 for making an IMOD display or display element. In some implementations, the manufacturing process 80 can be implemented to manufacture one or more EMS devices, such as IMOD displays or display elements. The manufacture of such an EMS device also can include other blocks not shown in FIG. 3. The process 80 begins at block 82 with the formation of the optical stack 16 over the substrate 20. FIG. 4A illustrates such an optical stack 16 formed over the substrate 20. The substrate 20 may be a transparent substrate such as glass or plastic such as the materials discussed above with respect to FIG. 1. The substrate 20 may be flexible or relatively stiff and unbending, and may have been subjected to prior preparation processes, such as cleaning, to facilitate efficient formation of the optical stack 16. As discussed above, the optical stack 16 can be electrically conductive, partially transparent, partially reflective, and partially absorptive, and may be fabricated, for example, by depositing one or more layers having the desired properties onto the transparent substrate 20.

In FIG. 4A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as the combined conductor/absorber sub-layer 16a. In some implementations, one of the sub-layers 16a and 16b can include molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form the rows of the display. In some implementations, at least one of the sub-layers of the optical stack, such as the optically absorptive layer, may be quite thin (e.g., relative to other layers depicted in this disclosure), even though the sub-layers 16a and 16b are shown somewhat thick in FIGS. 4A-4E.

The process 80 continues at block 84 with the formation of a sacrificial layer 25 over the optical stack 16. Because the sacrificial layer 25 is later removed (see block 90) to form the cavity 19, the sacrificial layer 25 is not shown in the resulting IMOD display elements. FIG. 4B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIG. 4E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 4C, the aperture formed in the sacrificial layer 25 can extend through the sacrificial layer 25, but not through the optical stack 16. For example, FIG. 4E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 4C, but also can extend at least partially over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIG. 4D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, the columns of the display. The movable reflective layer 14 can be electrically conductive, and referred to as an electrically conductive layer. In some implementations, the movable reflective layer 14 may include a plurality of sub-layers 14a, 14b and 14c as shown in FIG. 4D. In some implementations, one or more of the sub-layers, such as sub-layers 14a and 14c, may include highly reflective sub-layers selected for their optical and/or conductivity properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity 19. The cavity 19 may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

In some implementations, the packaging of an EMS component or device, such as an IMOD-based display, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

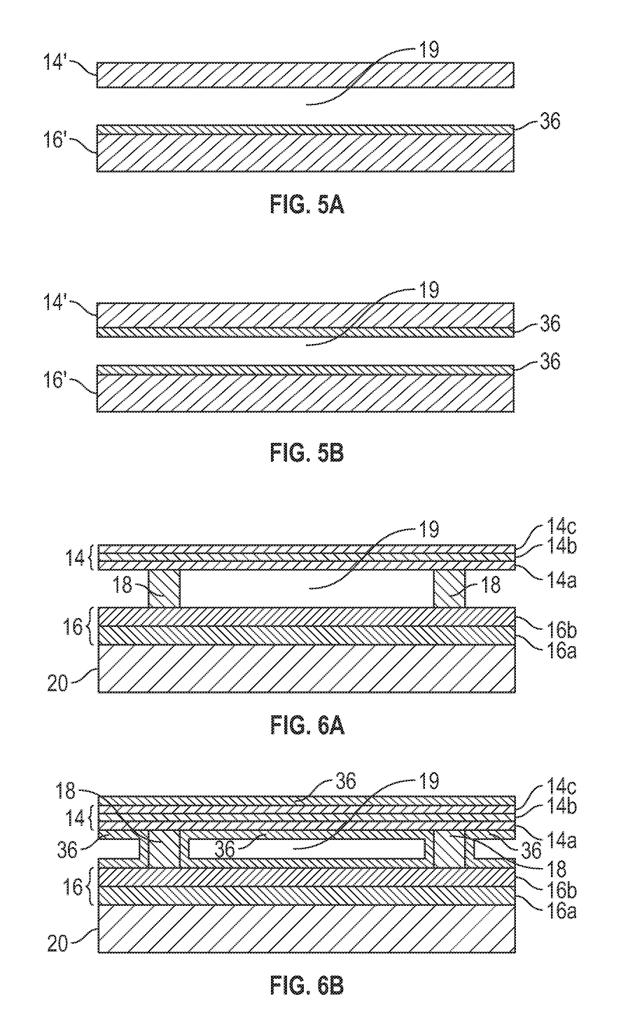

FIGS. 5A and 5B show examples of cross-sectional schematic illustrations of electromechanical systems devices. The electromechanical systems device includes a boron nitride layer 36, which can serve as an antistiction layer. In one implementation, the electromechanical systems device includes a first electrode 14′ and a second electrode 16′ that is separated from the first electrode 14′ by a cavity 19. At least one of the electrodes 14′ and 16′ is movable. In one implementation the first electrode 14′ is movable and the second electrode 16′ is stationary. In some implementations, at least one of the surface of the first electrode 14′ and the surface of the second electrode 16′ includes a boron nitride layer 36 exposed to the cavity 19, i.e., with no other layer between the boron nitride layer 36 and the cavity 19. FIG. 5A depicts an implementation in which only the surface of the second electrode 16′ includes the boron nitride layer 36. FIG. 5B shows an implementation in which both the surface of the first electrode 14′ and the surface of the second electrode 16′ include the boron nitride layer 36. While FIGS. 5A and 5B show the boron nitride layer 36 extending across the entire surface of the electrode, in some implementations, the boron nitride layer may extend along only a portion of the surface of the first electrode 14′ and/or the second electrode 16′.

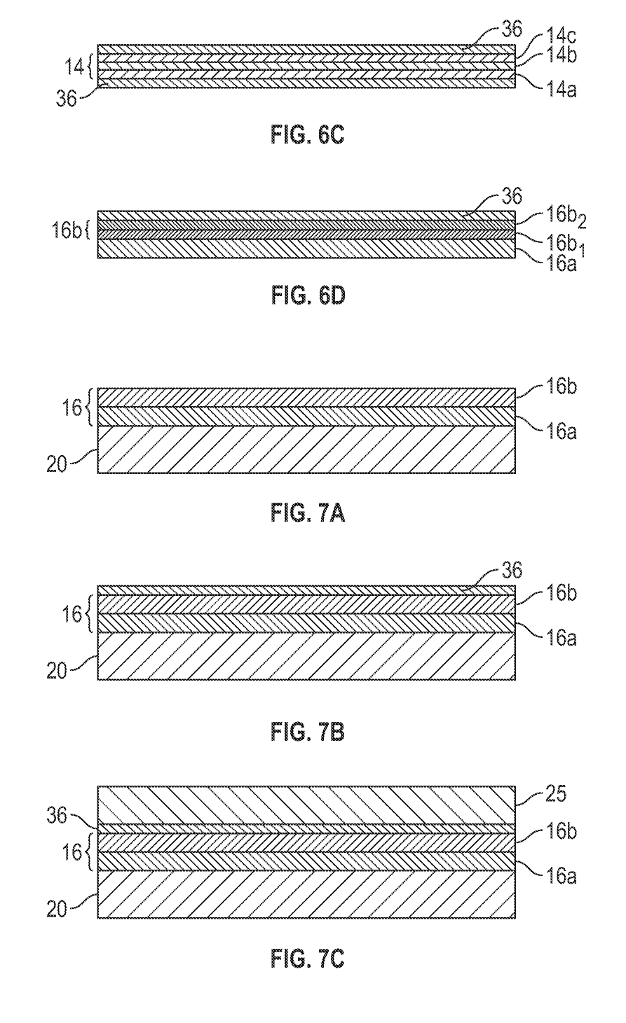

FIGS. 6A-6B show examples of cross-sectional schematic illustrations of stages in a method of making an interferometric modulator. FIG. 6A depicts an interferometric modulator similar to that illustrated in FIG. 4E. The interferometric modulator includes a substrate 20 and an optical stack 16 formed on the substrate. The optical stack 16 includes sub-layers 16a and 16b, at least one of which can be configured with both optically absorptive and conductive properties, as discussed above. For example, the optical stack 16 can include a combined conductor/optical absorber sub-layer 16a and a dielectric sub-layer 16b, which together form a first electrode structure. The first electrode structure, which can also be referred to as the optical stack 16 for an IMOD implementation, can serve as a stationary electrode for EMS operation.

The interferometric modulator includes a cavity 19 formed by the deposition and subsequent removal of a sacrificial layer, for example as described above with respect to FIGS. 4A-4E. Support structures 18 support a movable reflective layer 14 so that it is spaced from the substrate 20 and optical stack 16. It will be understood that the support structures can be independent, as shown, or can be integrated with the movable reflective layer 14. The movable reflective layer 14 can be electrically conductive and can include a plurality of sub-layers 14a, 14b and 14c. In some implementations, one or more of the sub-layers, such as sub-layers 14a and 14c, may include highly reflective sub-layers selected for their optical properties, and support layer 14b selected for its mechanical properties.

As shown in FIG. 6B, after release etching defines the cavity, at least the reflective layer 14a and top of the optical stack 16, and in the illustrated implementation all interior surfaces of the cavity 19, can be coated with a boron nitride layer 36. The coating may be a conformal boron nitride coating. The boron nitride layer 36 can be formed using atomic layer deposition (ALD). The boron nitride layer 36 can be formed by providing a reactant including boron in pulses alternated with pulses of a nitridizing agent. The deposition chamber can be pumped down and/or purged between reactant pulses to keep the mutually reactive reactants separated. For example, a boron precursor can self-limitingly adsorb onto the surface to form a monolayer or less in one pulse; excess boron precursor is removed from the deposition chamber, such as by purging; a nitridizing agent reacts with the adsorbed species of the boron precursor; and excess nitridizing agent is removed from the deposition chamber before the next precursor. Examples of boron precursors include trimethyl boron (TMB) and boron trichloride (BCl₃). An example nitridizing agent is ammonia (NH₃). Using these precursors can allow for a low process temperature. Each cycle leaves no more than about one monolayer of boron nitride in this example. In some implementations the reaction space has a temperature of about 200° C. to 400° C. during the alternate and sequential pulses of the ALD process, without plasma activation. In another implementation, temperatures can be dropped below about 200° C. with plasma activation. Deposition occurring around 200° C. can tend to deposit amorphous and/or polycrystalline boron nitride. Deposition occurring closer to 400° C. can tend to deposit more crystalline boron nitride. Regardless of deposition temperature or crystallinity of the deposited layer, the boron nitride can have a low surface energy. The above process can produce about 0.7 Å/cycle of BN with near perfect conformality within the cavity 19. The boron nitride layer 36 can be conformal over all the surfaces on which it is formed. In some implementations, a thinnest portion of the boron nitride layer is at least about 90% of the thickest portion of the boron nitride layer. A thickness of the boron nitride layer can be in the range of about 5 nm to 8 nm. The boron nitride layer 36 depositing using ALD may be formed on all exposed surfaces, including the surfaces around the cavity 19, the sides of the support structures 18 and the surface of the movable reflective layer 14 on the opposite side from the cavity 19, on the upper sub-layer 14c.

FIG. 6C shows an example of an enlarged cross-sectional schematic illustration of an interferometric modulator (e.g., the interferometric modulator illustrated in FIG. 6B). The cross-sectional schematic illustration of FIG. 6C includes an enlarged view of the movable reflective layer 14 and the boron nitride layer 36. As described above, the movable reflective layer can include sub-layers 14a, 14b and 14c. The sub-layers can include a reflective sub-layer 14a, a support layer 14b and a conductive layer 14c. A boron nitride layer 36 has been formed on the surface of the movable reflective layer 14 using atomic layer deposition. The boron nitride layer 36 can also be formed over the conductive layer 14c on the opposite side of the movable reflective layer 14 from the cavity 19.

FIG. 6D shows an example of an enlarged cross-sectional schematic illustration of an interferometric modulator (e.g., the interferometric modulator illustrated in FIG. 6B). The cross-sectional schematic illustration of FIG. 6D includes an enlarged view of the optical stack, including the sub-layers 16a and 16b, and the boron nitride layer. The boron nitride layer 36 can be formed on the surface of the optical stack using atomic layer deposition. As discussed above, in some implementations, the optical stack includes an optical absorber 16a, and a dielectric 16b, as shown in FIG. 6D. In some implementations, the sub-layer 16b can further include sub-layers which can provide properties such as insulating properties and/or etch stop properties. For example, in some implementations, a sub-layer 16b1 can include SiO₂ which can provide insulating properties, and can have a thickness of about 18-26 nm. A sub-layer 16b2 can include Al₂O₃ which can also provide insulating properties and may further provide etch stop properties, and can have a thickness of about 8-16 nm. As discussed above, a thickness of the boron nitride layer 36 can be about 4-8 nm. Thus, a thickness of the sub-layer 16b, including sub-layers 16b1 and 16b2, plus the thickness of the boron nitride layer 36 can be about 30-44 nm. In some implementations, a thickness of the layer 16b and the boron nitride layer is less than about 40 nm. In some implementations including a boron nitride layer, the thickness of the sub-layer 16b can be reduced as compared to a sub-layer 16b without a boron nitride layer for a given functionality (e.g., insulation and/or etch stop functionality). A reduced thickness of sub-layer 16b can, in some implementations, allow the thickness of the cavity 19 to be increased for a given desired optical effect, such as an optical pathlength for interferometrically enhancing a particular reflected color.

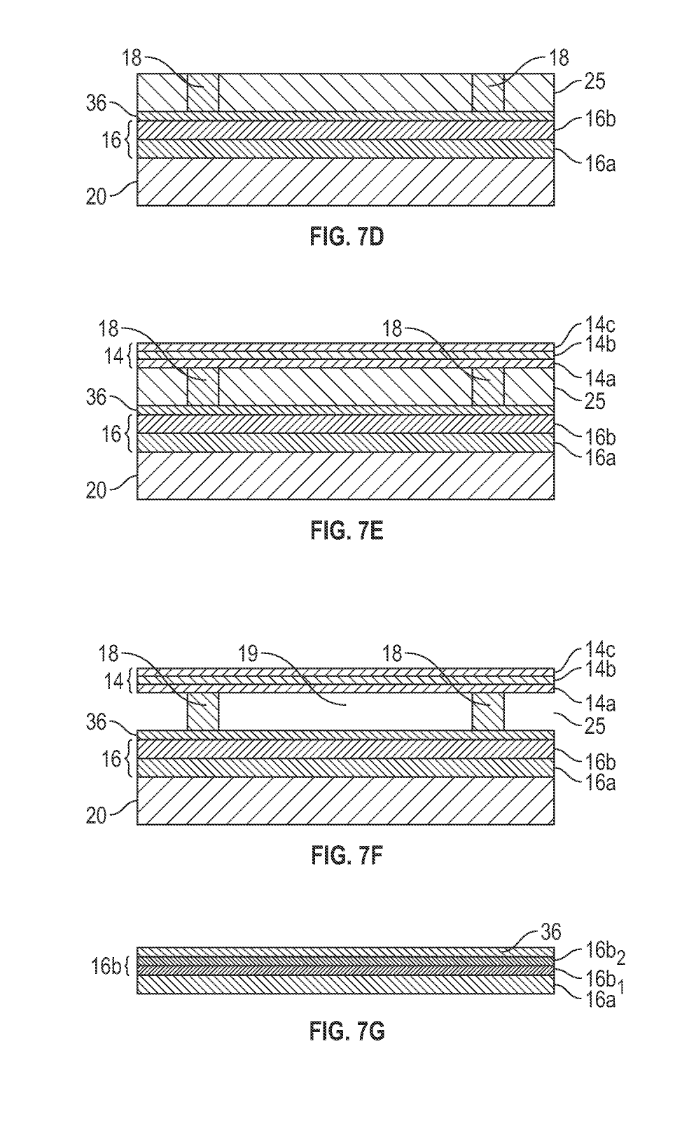

FIGS. 7A-7F show examples of cross-sectional schematic illustrations of various stages in a method of making an interferometric modulator. FIG. 7A depicts an initial stage of making the interferometric modulator including forming the optical stack 16 over the substrate 20. As discussed above, the substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 7A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). As discussed with respect to FIG. 6D, sub-layer 16b can include a first insulator 16b1 (e.g., including SiO₂) and a second insulator 16b2 (e.g., including Al₂O₃), which can also provide etch stop properties. As discussed below, with respect to FIG. 7B, in some implementations etch stop sub-layer 16b1 and/or 16b2 can be omitted and replaced by the boron nitride layer 36 which can also perform the etch stop function. In addition, the optical stack 16 can be patterned into individual and parallel strips that form the rows of the display.

The process continues with the formation of a boron nitride layer 36 over the optical stack 16. FIG. 7B illustrates a partially fabricated device including a boron nitride layer 36 formed over the optical stack 16. Deposition of the boron nitride layer may be carried out using deposition techniques such as physical vapor deposition (PVD, e.g., sputtering), plasma-enhanced chemical vapor deposition (PECVD), thermal chemical vapor deposition (thermal CVD), or atomic layer deposition (ALD), including but not limited to plasma enhanced ALD (PEALD) and UV assisted ALD (UVAALD).

The process continues with the formation of a sacrificial layer 25 over the optical stack 16. The sacrificial layer 25 is later removed to form the cavity 19 (see FIG. 7F). FIG. 7C illustrates a partially fabricated device including a sacrificial layer 25 formed over the optical stack 16 and the boron nitride layer 36. The formation of the sacrificial layer 25 over the optical stack 16 may include deposition of an etchable material in a thickness selected to provide, after subsequent removal, a gap or cavity 19 having a desired design size. The sacrificial material can be selectively etchable relative to the exposed permanent materials of the EMS device. In some implementations, the etchable material can be a fluorine-etchable material, such as molybdenum (Mo) or amorphous silicon (a-Si). Other materials are also contemplated. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

As shown in FIG. 7D, the process continues with the formation of a support structure 18. The formation of the support structure 18 may include patterning the sacrificial layer 25 to form a support structure aperture, then depositing a material (e.g., a polymer or an inorganic material, such as silicon oxide) into the aperture to form the post 18, using a deposition method such as PVD, PECVD, thermal CVD, or spin-coating. In some implementations, the support structure aperture formed in the sacrificial layer can extend through sacrificial layer, but not through the boron nitride layer 36 or the optical stack 16, as shown in FIG. 7D. In some implementations, the support structure aperture formed in the sacrificial layer can extend through the sacrificial layer 25, the boron nitride layer 36, and the optical stack 16 to the underlying substrate 20, similar to the example shown in FIGS. 2A and 2B, so that the lower end of the post 18 contacts the substrate 20. Alternatively, the aperture formed in the sacrificial layer 25 can extend through the sacrificial layer 25 and the boron nitride layer 36, but not through the optical stack 16. The support structures 18 may be formed by depositing a layer of support structure material over the sacrificial layer 25 and patterning portions of the support structure material located away from apertures in the sacrificial layer 25. The support structures may be located within the apertures, as illustrated in FIG. 6C, but also can, at least partially, extend over a portion of the sacrificial layer 25. As noted above, the patterning of the sacrificial layer 25 and/or the support structures 18 can be performed by a patterning and etching process, but also may be performed by alternative etching methods. The support structures 18 can also be integrally formed with the formation of the movable reflective layer 14, as discussed with respect to FIG. 7E.

As shown in FIG. 7E, the process continues with the formation of a movable reflective layer such as the movable reflective layer 14 illustrated in any of FIGS. 2A-2E. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b and 14c as shown in FIG. 7F. In some implementations, one or more of the sub-layers, such as sub-layers 14a and 14c, may include highly reflective sub-layers selected for their optical properties, and a support layer 14b may be selected for its mechanical properties. Since the sacrificial layer 25 is still present in the partially fabricated interferometric modulator shown in FIG. 7E, the movable reflective layer 14 is typically not movable at this stage. A partially fabricated IMOD that contains a sacrificial layer 25 may also be referred to herein as an “unreleased” IMOD, in this case including a buried boron nitride layer 36. As described above in connection with FIG. 1, the movable reflective layer 14 can be patterned into individual and parallel strips that form the columns of the display.

FIG. 7F depicts the device after the formation of a cavity. The cavity 19 may be formed by exposing the sacrificial material 25 to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ or other fluorine sources for a period of time that is effective to remove the desired amount of material, typically selectively removed relative to the structures surrounding the cavity 19. Other etching methods, e.g. wet etching and/or plasma etching, also may be used. Since the sacrificial layer 25 is removed, the movable reflective layer 14 is typically movable after this stage. After removal of the sacrificial material 25, the resulting fully or partially fabricated IMOD may be referred to herein as a “released” IMOD. As shown, the boron nitride layer 36 is positioned such that, after release, it is exposed to the cavity 19 with no intervening layers.

FIG. 7G shows an example of an enlarged cross-sectional schematic illustration of an interferometric modulator (e.g., the interferometric modulator illustrated in FIG. 6B). The cross-sectional schematic illustration of FIG. 7G includes an enlarged view of the optical stack, including the sub-layers 16a and 16b, and the boron nitride layer. The boron nitride layer 36 can be formed on the surface of the optical stack using atomic layer deposition. As discussed above, in some implementations, the optical stack includes an optical absorber 16a, and a dielectric 16b, as shown in FIG. 6D. In some implementations, a thickness of the sub-layer 16b can be reduced as compared to a sub-layer 16b without a boron nitride layer for a given functionality. A reduced thickness of sub-layer 16b can, in some implementations, allow the thickness of the cavity 19 to be increased for a given desired optical effect, such as an optical pathlength for interferometrically enhancing a particular reflected color.

In some implementations, the boron nitride layer 36 can function as an etch stop during patterning of the sacrificial layer 25, allowing for the omission of sub-layer 16b2, and further reducing the thickness of sub-layer 16b1. Accordingly, an overall thickness of the boron nitride layer 36 and the sub-layer 16b can be about 22-32 nm. As described above, a reduced thickness of sub-layer 16b can, in some implementations, allow the thickness of the cavity 19 to be increased for a given desired optical effect, such as an optical pathlength for interferometrically enhancing a particular reflected color.

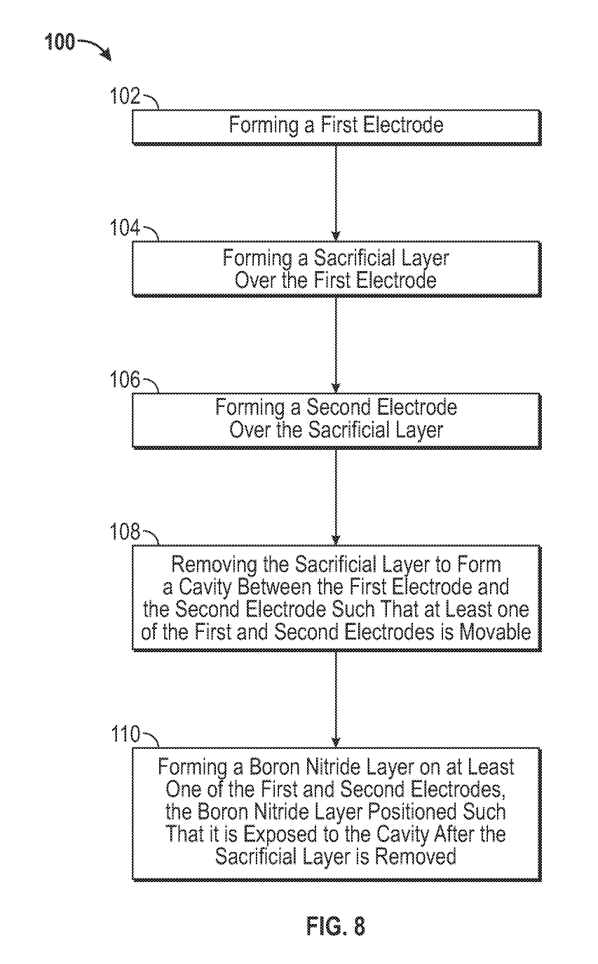

FIG. 8 shows an example of a flow diagram illustrating a method for processing electromechanical systems devices. The method need not be conducted in the illustrated sequence. In some implementations, the method 100 can include, at block 102, forming a first electrode. At block 104, a sacrificial layer can be formed over the first electrode. At block 106, a second electrode can be formed over the sacrificial layer. At block 108, the sacrificial layer can be removed, forming a cavity between the first electrode and the second electrode, such that at least one of the first electrode and the second electrode is movable. The electromechanical systems device can be referred to as ‘released’ after removal of the sacrificial layer. At block 108, a boron nitride layer can be formed on at least one of the first and second electrodes. The boron nitride layer can be positioned such that it is exposed to the cavity after the sacrificial layer is removed.

In some implementations, the boron nitride layer may be formed before formation of the sacrificial layer, for example, as illustrated in FIGS. 7A-7F above and by any of a variety of deposition techniques, such as PVD, CVD or ALD. In other implementations, the boron nitride layer may be formed after formation and removal of the sacrificial layer, for example as illustrated in FIGS. 6A-6B above and can be formed by ALD.

In some implementations, the electromechanical systems device is an interferometric modulator.

In some implementations, the boron nitride layer 36 has a hardness of about 3400 kg/mm²-4500 kg/mm².

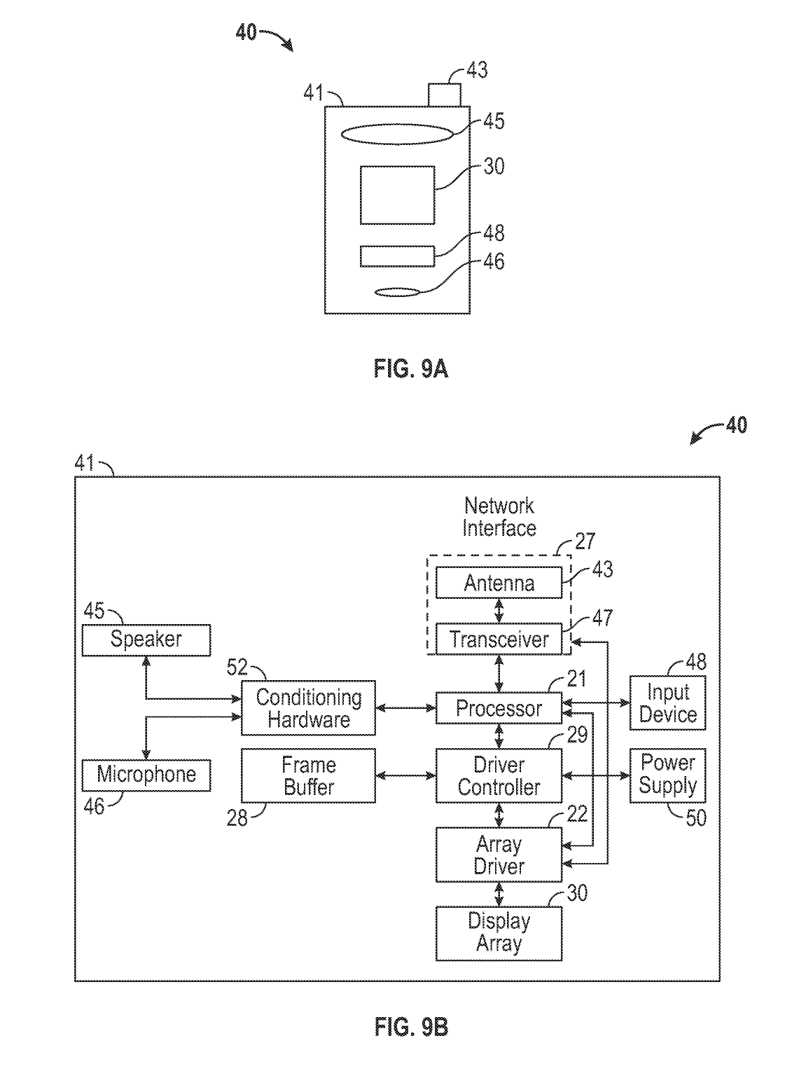

FIGS. 9A and 9B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 9B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9B, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An optical electromechanical systems device comprising:
a first electrode structure having a first surface;
a second electrode structure having a first surface and a second surface opposite the first surface, the second electrode structure being movable for operation of the optical electromechanical systems device;
a collapsible cavity between the first surface of the first electrode structure and the first surface of the second electrode structure; and
a boron nitride layer exposed to the cavity and over at least one of the first surface of the first electrode structure and the first surface of the second electrode structure.

2. The device of claim 1, wherein the boron nitride layer lines the cavity on both the first surface of the first electrode structure and the first surface of the second electrode structure.

3. The device of claim 2, wherein the boron nitride layer at least partially covers the second surface of the second electrode structure.

4. The device of claim 1, wherein the boron nitride layer is only on the first surface of the first electrode structure.

5. The device of claim 1, wherein the boron nitride layer has a hardness between about 3400 kg/mm² and about 4500 kg/mm².

6. The device of claim 1, wherein the first surface of the first electrode structure is defined by an insulator over a conductive optical absorber layer and wherein the boron nitride layer lines the cavity on the first surface of the first electrode structure.

7. The device of claim 6, wherein a thickness of the insulator and the boron nitride layer is less than about 45 nm.

8. The device of claim 1, wherein a thickness of the insulator and the boron nitride layer is about 30-40 nm.

9. The device of claim 1, wherein a thickness of the insulator and the boron nitride layer is about 22-42 nm.

10. The device of claim 1, wherein a thickness of the boron nitride layer is about 4-8 nm.

11. The device of claim 1, wherein the boron nitride layer is conformal over at least one of the first surface of the first electrode structure and the first surface of the second electrode structure.

12. The device of claim 1, wherein a majority of the first electrode structure is parallel to the second electrode structure in each of open and closed states.

13. The device of claim 1, wherein the second electrode structure is connected to the second electrode structure around a perimeter of the second electrode structure by support structures.

14. The device of claim 13, configured such that a middle portion of the second electrode structure deflects towards the first electrode structure when in a closed state.

15. The device of claim 1, wherein the second electrode structure comprises a mirror layer.

16. The device of claim 1, wherein the electromechanical systems device is an interferometric modulator.

17. A display apparatus, including
the device of claim 1;
a display;
a processor that is configured to communicate with the display, the processor being configured to process image data; and
a memory device that is configured to communicate with the processor.

18. The apparatus of claim 17, further comprising:
a driver circuit configured to send at least one signal to the display; and
a controller configured to send at least a portion of the image data to the driver circuit.

19. The apparatus of claim 17, further comprising:
an image source module configured to send the image data to the processor,
wherein the image source module includes at least one of a receiver, transceiver, and transmitter.

20. The apparatus of claim 17, further comprising;
an input device configured to receive input data and to communicate the input data to the processor.

21. A method for manufacturing an optical electromechanical systems device comprising:
forming a first electrode;
forming a sacrificial layer over the first electrode;
forming a second electrode over the sacrificial layer;
removing the sacrificial layer, thereby releasing the optical electromechanical systems device and forming a cavity between the first electrode and the second electrode such that at least one of the first and second electrodes is movable; and
forming a boron nitride layer on at least one of the first and second electrodes, the boron nitride layer positioned such that it is exposed to the cavity after the sacrificial layer is removed.

22. The method of claim 21, wherein forming the boron nitride layer includes depositing a conformal layer in the cavity by atomic layer deposition after removing the sacrificial layer.

23. The method of claim 22, wherein depositing a conformal layer in the cavity by atomic layer deposition includes alternating pulses of a trimethyl boron (TMB) or boron trichloride (BCl₃) precursor and an ammonia (NH₃) precursor.

24. The method of claim 23, wherein the deposition is performed at a temperature of about 200° C.-400° C.

25. The method of claim 21, wherein forming the boron nitride layer includes depositing a boron nitride layer over the first electrode before forming the sacrificial layer over the first electrode.

26. The method of claim 21, further including forming support structures configured to support the second electrode around a perimeter of the second electrode.

27. An optical electromechanical systems device comprising:
a first electrode;
a second electrode that is movable for operation of the optical electromechanical systems device;
a cavity defined between the first electrode and the second electrode; and
a means for reducing stiction covering a surface of at least one of the first electrode and the second electrode exposed to the cavity, the means for reducing stiction including boron nitride.

28. The device of claim 27, wherein the means for reducing stiction includes a boron nitride layer on surfaces facing the cavity of each of the first electrode and second electrode.

29. The device of claim 27, wherein the second electrode is substantially parallel to the first electrode in each of an open state and a closed state.

30. The device of claim 27, wherein the second electrode is suspended above the first electrode by support structures.

31. The device of claim 30, wherein a portion of the second electrode between the support structures has a tensile stress.
